(19) United States
(12) Patent Application Publication
(10) Pub. No.: US 2013/0152990 A1
(43) Pub. Date: Jun. 20, 2013

(54) SOLID-LIQUID INTERDIFFUSION BONDING STRUCTURE OF THERMOELECTRIC MODULE AND FABRICATING METHOD THEREOF

(71) Applicants: Hong-Jen Lai, Hsinchu City (TW); Jenn-Dong Hwang, Hsinchu City (TW); Hsu-Shen Chu, Hsinchu City (TW); Tung-Han Chuang, Taipei City (TW); Chao-Chi Jain, Nantou County (TW); Che-Wei Lin, Taipei City (TW)

(72) Inventors: Hong-Jen Lai, Hsinchu City (TW); Jenn-Dong Hwang, Hsinchu City (TW); Hsu-Shen Chu, Hsinchu City (TW); Tung-Han Chuang, Taipei City (TW); Chao-Chi Jain, Nantou County (TW); Che-Wei Lin, Taipei City (TW)

(21) Appl. No.: 13/668,306

(22) Filed: Nov. 4, 2012

(30) Foreign Application Priority Data
Dec. 20, 2011 (TW) 100147410

(51) Int. Cl. H01L 35/08; H01L 35/34; H01L 35/18; B23K 31/02; H01L 35/16

(52) U.S. Cl. 136/237; 228/256; 228/176; 136/200

(57) ABSTRACT

A solid-liquid interdiffusion bonding structure of a thermoelectric module and a fabricating method thereof are provided. The method includes coating a silver, nickel, or copper layer on surfaces of a thermoelectric component and an electrode plate, and then coating a tin layer. A thermocompression treatment is performed on the thermoelectric component and the electrode plate, such that the melted tin layer reacts with the silver, nickel, or copper layer to form a silver-tin intermetallic compound, a nickel-tin intermetallic compound, or a copper-tin intermetallic compound. After cooling, the thermoelectric component and the electrode plate are bonded together.

### CROSS-REFERENCE TO RELATED APPLICATION

This application claims the priority benefit of Taiwan application serial no. 100147410, filed on Dec. 20, 2011. The entirety of the above-mentioned patent application is hereby incorporated by reference herein and made a part of this specification.

### TECHNICAL FIELD

The disclosure relates to a solid-liquid interdiffusion bonding structure of a thermoelectric module and a fabricating method thereof.

### BACKGROUND

Generally, thermoelectric transmission power or thermoelectric transform efficiency of a single thermoelectric component is definitely limited. Hence, metallic electrodes are commonly used to connect a plurality of thermoelectric components to form a thermoelectric module so as to increase the thermoelectric transmission power or thermoelectric transform efficiency.

Conventionally, a soldering method is introduced to bond the thermoelectric component and the metallic electrode. The soldering bonding method is often performed at the temperature range from 200° C. to 300° C. with tin or a tin alloy which has a lower melting point. After the soldering process, the tin or tin alloy having the lower melting point is still remained. Even though a thermal stress generated in this soldering bonding process is low, an operation temperature of the formed thermoelectric module is limited to the melting point of the tin or tin alloy. That means the operation temperature of the thermoelectric module formed with the conventional soldering method must be lower than the melting point of the tin (at 232° C.) or tin alloy (near 232° C.).

In order to increase the operation temperature of the thermoelectric module, a brazing bonding method is provided, in which a filling metal having a high melting point is used. However, the brazing bonding method is needed to perform at a temperature higher than 450° C. After the brazing bonding process and cooling to a room temperature, a large thermal stress is generated owing to the thermal expansion coefficient difference between the thermoelectric component and the metallic electrode, and thereby the bonding interface is easily damaged.

Moreover, a solid-liquid interdiffusion (SLID) bonding method is applied to an integrated circuit process. In addition, a Au—In alloy and a laser gyroscope are used to bond quartz, ceramics and metallic components so as resolve the thermal expansion coefficient difference issue and increase the operation temperature of the devices. Furthermore, the SLID method is applied to a micro-electromechanical system (MEMS) device, in which a Cr layer is coated on a chip and a bonding device, and then Au and In are coated on the Cr layer so as to form Au—In alloy to increase a bonding strength and increase the operation temperature.

### SUMMARY

A method of fabricating a solid-liquid interdiffusion bonding structure of a thermoelectric module includes forming a silver, nickel, or copper layer on at least one of a thermoelectric component and an electrode plate, and then forming a tin layer. The thermoelectric component and the electrode plate are stacked together and a thermocompression treatment is performed, such that the tin layer reacts with the silver, nickel, or copper layer to form a silver-tin intermetallic compound, a nickel-tin intermetallic compound, or a copper-tin intermetallic compound. After cooling, the thermoelectric component and the electrode plate are bonded. Herein, the tin layer completely reacts with the silver, nickel, or copper layer to form the silver-tin intermetallic compound, the nickel-tin intermetallic compound, or the copper-tin intermetallic compound, and the silver, nickel, or copper layer is partially remained.

A solid-liquid interdiffusion bonding structure of a thermoelectric module includes at least one thermoelectric component and at least one electrode plate, and a bonding layer is between the thermoelectric component and the electrode plate so as to bond the thermoelectric component and the electrode plate together. The bonding layer comprises a silver-tin intermetallic compound, a nickel-tin intermetallic compound, or a copper-tin intermetallic compound.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 to FIG. 4 are cross-sectional views illustrating a method of fabricating a solid-liquid interdiffusion bonding structure of a thermoelectric module according to an exemplary embodiment.

### DETAILED DESCRIPTION OF DISCLOSED EMBODIMENTS

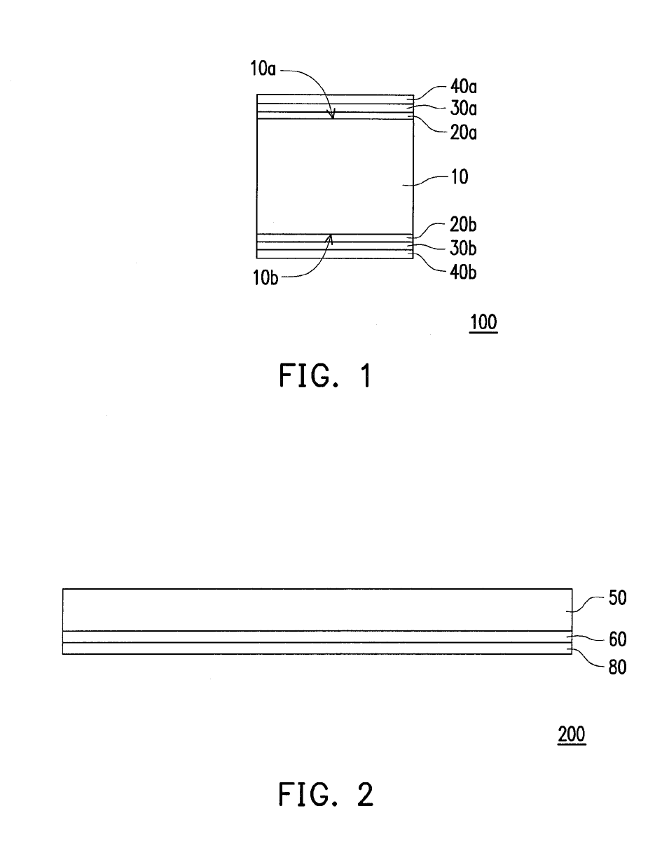

FIG. 1 to FIG. 4 are cross-sectional views illustrating a method of fabricating a solid-liquid interdiffusion bonding structure of a thermoelectric module according to an exemplary embodiment. Referring to FIG. 1, the method of the exemplary embodiment includes providing at least one thermoelectric component 10. According to the exemplary embodiment, the thermoelectric component 10 comprises a thermoelectric material, such as a p-type thermoelectric material or an n-type thermoelectric material, and the thermoelectric material comprises an alloy series of Bi₂Te₃, GeTe, PbTe, CoSb₃, or Zn₄Sb₃ for instance, which should not be construed as a limitation to the disclosure.

The thermoelectric component 10 has a first surface 10a and a second surface 10b. A silver, nickel, or copper layer 30a and a tin layer 40a are formed on the first surface 10a of the thermoelectric component 10. A barrier layer 20a may further be formed on the first surface 10a of the thermoelectric component 10. In the exemplary embodiment, a thickness of the silver, nickel, or copper layer 30a ranges from 2 μm to 10 μm, and a thickness of the tin layer 40a ranges from 1 μm to 10 μm. In addition, the barrier layer 20a comprises nickel, or any other appropriate material capable of preventing metal element diffusion, and a thickness of the barrier layer 20a ranges from 1 μm to 5 μm.

In the exemplary embodiment, in addition to the silver, nickel, or copper layer 30a and the tin layer 40a formed on the first surface 10a of the thermoelectric component 10, a silver, nickel, or copper layer 30b and a tin layer 40b are further formed on the second surface 10b of the thermoelectric component 10, and a barrier layer 20b may further be formed on the second surface 10b of the thermoelectric component 10. A thickness of the silver, nickel, or copper layer 30b ranges from 2 μm to 10 μm, and a thickness of the tin layer 40b ranges from 1 μm to 10 μm. In addition, the barrier layer 20b comprises nickel, or any other appropriate material capable of preventing metal element diffusion, and a thickness of the barrier layer 20b ranges from 1 μm to 5 μm. The silver, nickel, or copper layer 30a and the tin layer 40a on the first surface 10a of the thermoelectric component 10 and the silver, nickel, or copper layer 30b and the tin layer 40b on the second surface 10b of the thermoelectric component 10 are respectively formed with an electroplating process, an electroless plating process, a vacuum evaporation process, a sputtering process, or a chemical vapor deposition process, for example.

The barrier layer 20a, the silver, nickel, or copper layer 30a and the tin layer 40a on the first surface 10a of the thermoelectric component 10, the barrier layer 20b, the silver, nickel, or copper layer 30b and the tin layer 40b on the second surface 10b of the thermoelectric component 10, and the thermoelectric component 10 form a stacked structure 100.

Referring to FIG. 2, at least one electrode plate 50 is provided. The electrode plate 50 is a copper electrode plate or any other appropriate electrode plate. A silver, nickel, or copper layer 60 and a tin layer 80 are formed on a surface of the electrode plate 50. A thickness of the silver, nickel, or copper layer 60 ranges from 2 μm to 10 μm, and a thickness of the tin layer 80 ranges from 1 μm to 10 μm. The silver, nickel, or copper layer 60 and the tin layer 80 on the electrode plate 50 and the electrode plate 50 form a stacked structure 200. The silver, nickel, or copper layer 60 and the tin layer 80 on the electrode plate 50 are respectively formed with an electroplating process, an electroless plating process, a vacuum evaporation process, a sputtering process, or a chemical vapor deposition process, for example.

It is noted that in the exemplary embodiment of FIG. 1, the stacked structure 100 having the thermoelectric component 10 includes the silver, nickel, or copper layers 30a, 30b and the tin layers 40a, 40b thereon, and the stacked structure 200 having the electrode plate 50 includes the silver, nickel, or copper layer 60 and the tin layer 80 thereon, which should not be construed as a limitation to the disclosure. According to another exemplary embodiment, the stacked structure 100 having the thermoelectric component 10 only includes the silver, nickel, or copper layers 30a, 30b thereon, and the stacked structure 200 having the electrode plate 50 includes the silver, nickel, or copper layer 60 and the tin layer 80 thereon. According to another exemplary embodiment, the stacked structure 100 having the thermoelectric component 10 includes the silver, nickel, or copper layers 30a, 30b and the tin layers 40a, 40b thereon, and the stacked structure 200 having the electrode plate 50 only includes the silver, nickel, or copper layer 60 thereon. Namely, the tin layer can be formed on one of the thermoelectric component 10 and the electrode plate 50, or formed on both of the thermoelectric component 10 and the electrode plate 50.

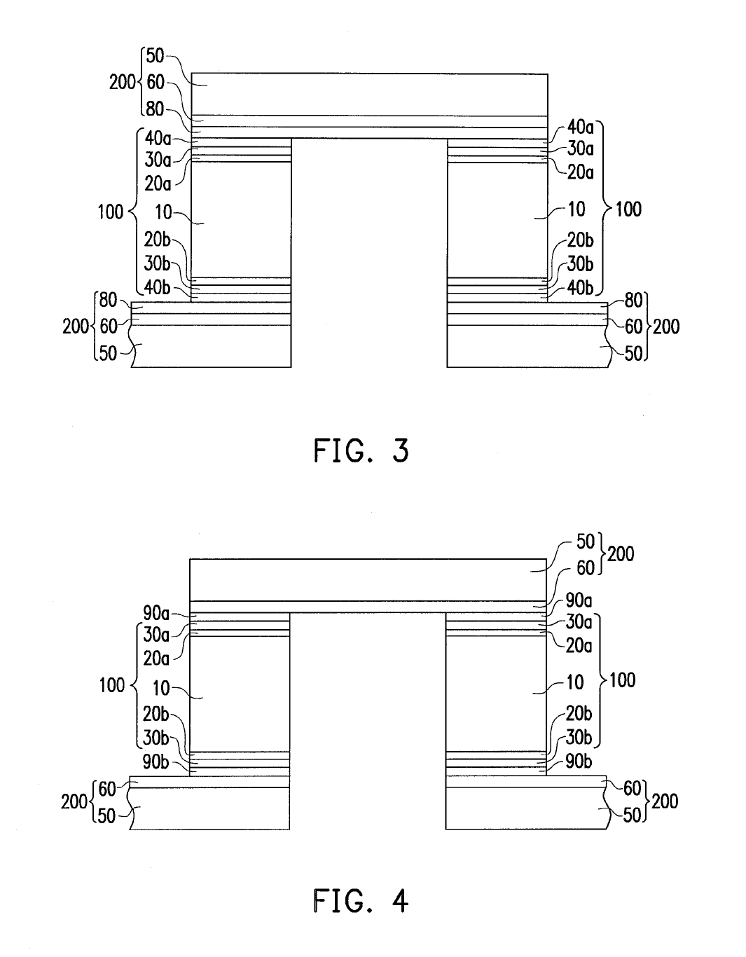

Referring to FIG. 3, the thermoelectric component 10 (the stacked structure 100) and the electrode plate 50 (the stacked structure 200) are stacked together such that the tin layers 40a, 40b on the thermoelectric component 10 contact to the tin layers 80 on the electrode plate 50.

In the exemplary embodiment, two sides of each thermoelectric component 10 (the stacked structure 100) are respectively stacked with one electrode plate 50 (the stacked structure 200). A thermoelectric module can be formed from a plurality of thermoelectric components 10 (stacked structures 100) and a plurality of electrode plates 50 (stacked structures 200) stacked together. In the exemplary embodiment, the thermoelectric module including two thermoelectric components 10 (stacked structures 100) and three electrode plates 50 (stacked structures 200) stacked together is taken as an example for descriptions. The disclosure does not limit the number of thermoelectric components (stacked structures 100) and the number of the electrode plates 50 (stacked structures 200) in the thermoelectric module.

Referring to FIG. 4, a thermocompression treatment is performed such that the tin layers 40a, 40b and the tin layer 80 react with the silver, nickel, or copper layers 30a, 30b and the silver, nickel, or copper layer 60 to form a silver-tin intermetallic compound, a nickel-tin intermetallic compound, or a copper-tin intermetallic compound. After a cooling step is performed to a room temperature, bonding layers 90a, 90b comprising the silver-tin intermetallic compound, the nickel-tin intermetallic compound, or the copper-tin intermetallic compound are formed, such that the thermoelectric component and the electrode plate are bonded together.

In the exemplary embodiment, the thermocompression treatment is performed under a pressure of 1 MPa to 10 MPa at a temperature ranged from 235° C. to 350° C. for 3-60 minutes. The thermocompression treatment is performed in a vacuum condition or in an inert gas condition, and the temperature of the thermocompression treatment is higher than a melting point of the tin layer and the pressure of the thermocompression treatment is enough to eliminate the voids at the bonding interface while not to cause the breakage of the thermoelectric component. During the thermocompression treatment, the tin layer having a lower melting point is melted and reacts with the silver, nickel, or copper layer having a higher melting point, and the tin layer is completely reacted and consumed to form the intermetallic compound containing tin. The foregoing bonding process is referred to a solid-liquid interdiffusion bonding process.

For detail, if the silver, nickel, or copper layers 30a, 30b, 60 are silver, the silver layers 30a, 30b, 60 should be thick or much enough such that the tin film films 40a, 40b, 80 can be completely reacted and consumed to form the intermetallic compound. For instance, an atom ratio of Ag:Sn between the silver layers 30a, 30b, 60 and the tin film films 40a, 40b, 80 is larger than 3:1. Accordingly, the tin layers 40a, 40b, 80 having the lower melting point are melted and completely reacted with the silver layers 30a, 30b, 60 having the higher melting point. After that, the silver-tin intermetallic compound comprising Ag₃Sn is formed, wherein the tin layers 40a, 40b, 80 are completely consumed and the silver layers 30a, 30b, 60 are partially remained. If the silver, nickel, or copper layers 30a, 30b, 60 are silver, the formed silver-tin intermetallic compound (Ag₃Sn) has a melting point about 480° C. after the thermocompression treatment (from 235° C. to 350° C.). That means the thermoelectric module having the bonding structure can be operated at temperatures higher than 232° C. and lower than 480° C.

If the silver, nickel, or copper layers 30a, 30b, 60 are nickel, the nickel-tin intermetallic compound comprises Ni₃Sn₄, Ni₃Sn₂, Ni₃Sn, or a combination thereof after the liquid inter-diffusion bonding process. Similarly, the nickel layers 30a, 30b, 60 should be thick or much enough such that the tin thin films 40a, 40b, 80 can be completely reacted and consumed to form the intermetallic compound. For instance, an atom ratio of Ni:Sn between the nickel layers 30a, 30b, 60 and the tin film films 40a, 40b, 80 is larger than 3:4. Accordingly, the tin layers 40a, 40b, 80 having the lower melting point are melted and completely reacted with the nickel layers 30a, 30b, 60 having the higher melting point. After that, the nickel-tin intermetallic compound comprising Ni₃Sn₄, Ni₃Sn₂, Ni₃Sn, or a combination thereof is formed, wherein the tin layers 40a, 40b, 80 are completely consumed and the nickel layers 30a, 30b, 60 are partially remained. If the silver, nickel, or copper layers 30a, 30b, 60 are nickel, the formed nickel-tin intermetallic compound (Ni₃Sn₄) has a melting point about 796° C., the formed nickel-tin intermetallic compound (Ni₃Sn₂) has a melting point about 1267° C., and the formed nickel-tin intermetallic compound (Ni₃Sn) has a melting point about 1169° C. after the thermocompression treatment (from 235° C. to 350° C.). That means the thermoelectric module having the bonding structure can be operated at temperatures higher than 232° C. and lower than 796° C.

If the silver, nickel, or copper layers 30a, 30b, 60 are copper, the nickel-tin intermetallic compound comprises Cu₆Sn₅, Cu₃Sn, or a combination thereof after the solid-liquid interdiffusion bonding process. Similarly, the copper layers 30a, 30b, 60 should be thick or much enough such that the tin thin films 40a, 40b, 80 can be completely reacted and consumed to form the intermetallic compound. For instance, an atom ratio of Cu:Sn between the copper layers 30a, 30b, 60 and the tin thin films 40a, 40b, 80 is larger than 6:5. Accordingly, the tin layers 40a, 40b, 80 having the lower melting point are melted and completely reacted with the copper layers 30a, 30b, 60 having the higher melting point. After that, the copper-tin intermetallic compound comprising Cu₆Sn₅, Cu₃Sn, or a combination thereof is formed, wherein the tin layers 40a, 40b, 80 are completely consumed and the copper layers 30a, 30b, 60 are partially remained. If the silver, nickel, or copper layers 30a, 30b, 60 are copper, the formed copper-tin intermetallic compound (Cu₆Sn₅) has a melting point about 415° C., and the formed copper-tin intermetallic compound (Cu₃Sn) has a melting point about 640° C. after the thermocompression treatment (from 235° C. to 350° C.). That means the thermoelectric module having the bonding structure can be operated at temperatures higher than 232° C. and lower than 415° C.

The solid-liquid interdiffusion bonding structure of the thermoelectric module formed with the foregoing process is as shown in FIG. 4, which includes at least one thermoelectric component 10 and at least one electrode plate 50, and bonding layers 90a, 90b are between the thermoelectric component 10 and the electrode plate 50 so as to so bond the thermoelectric component 10 and the electrode plate 50 together. The bonding layers 90a, 90b comprises the silver-tin intermetallic compound, the nickel-tin intermetallic compound, or the copper-tin intermetallic compound.

The thermoelectric component 10 comprises a thermoelectric material, such as a p-type thermoelectric material or an n-type thermoelectric material, and the thermoelectric material includes an alloy series of Bi₂Te₃, GeTe, PbTe, CoSb₃, or Zn₄Sb₃ for instance. The bonding layers 90a, 90b further comprise a residue layer of the silver, nickel, or copper layers 30a, 30b. The barrier layers 20a, 20b may further be formed between the bonding layers 90a, 90b and the thermoelectric component 10, and a thickness of the barrier layers 20a, 20b ranges from 1 μm to 5 μm.

The bonding layers 90a, 90b comprises the silver-tin intermetallic compound, the nickel-tin intermetallic compound, or the copper-tin intermetallic compound. The silver-tin intermetallic compound comprises Ag₃Sn, the nickel-tin intermetallic compound comprises Ni₃Sn₄, Ni₃Sn₂, Ni₃Sn, or a combination thereof, and the copper-tin intermetallic compound comprises Cu₆Sn₅, Cu₃Sn, or a combination thereof. Since the melting point of the silver-tin intermetallic compound, the nickel-tin intermetallic compound, or the copper-tin intermetallic compound is much higher than the temperature of the thermocompression treatment, the thermoelectric component—and the electrode plate can be bonded at a lower temperature to reduce thermal stress effect and the thermoelectric module can be operated at a higher temperature.

### EXAMPLE 1

The thermoelectric module of Example 1 is formed by coating a nickel layer having a thickness about 4 μm and a silver layer having a thickness about 10 μm on a p-type thermoelectric component (Bi_{0.5}Sb_{1.5}Te₃), and coating a silver layer having a thickness about 2 μm and a tin layer having a thickness about 4 μm on an copper electrode plate. After that, the thermoelectric component having the nickel layer and the silver layer and the copper electrode plate having the silver layer and the tin layer are stacked together, and then a thermocompression treatment is performed in a vacuum condition or an inert gas condition. The thermocompression treatment is performed under a pressure of 2 MPa at a temperature about 300° C. for 30 minutes, and the tin layer on the copper electrode plate is melted and quickly reacted with the silver layers on the thermoelectric component and the electrode plate to form a bonding layer comprising the silver-tin intermetallic compound (Ag₃Sn). Because the tin layer is thin (4 μm), the tin layer can be quickly reacted and completely consumed, and the silver layers are partially remained.

The bonding layer comprises the silver-tin intermetallic compound (Ag₃Sn). Since the melting point of the silver-tin intermetallic compound (Ag₃Sn) is about 480° C., the thermoelectric module of Example 1 can be operated at temperatures higher than 232° C. and lower than 480° C. In addition, the bonding layer in the thermoelectric module of Example 1 is tested with a shear strength test, and the test result presents the bonding layer has a bonding strength about 10.0 MPa. In another case, the thermoelectric module is bonded under 2 MPa at a temperature about 250° C. for 10 minutes, which results in a bonding strength of 3.6 MPa. Increasing the pressure of thermocompression process from 2 MPa to 9 MPa leads to a bonding strength of 13.7 MPa.

### EXAMPLE 2

The thermoelectric module of Example 2 is formed by coating a tin layer having a thickness about 2 μm, a nickel layer having a thickness about 4 μm and a silver layer having a thickness about 10 μm on a n-type thermoelectric component (Bi₂Te_{2.55}Se_{0.45}), and coating a silver layer having a thickness about 2 μm and a tin layer having a thickness about 4 μm on an copper electrode plate. After that, the thermoelectric component having the tin layer, the nickel layer and the silver layer and the copper electrode plate having the silver layer and the tin layer are stacked together, and then a thermocompression treatment is performed in a vacuum condition or an inert gas condition. The thermocompression treatment is performed under a pressure of 2 MPa at a temperature about 300° C. for 30 minutes, and the tin layer on the copper electrode plate is melted and quickly reacted with the silver layers on the thermoelectric component and the copper electrode plate to form a bonding layer comprising the silver-tin intermetallic compound (Ag₃Sn). The tin layer is quickly reacted and is completely consumed, and the silver layers are partially remained.

The bonding layer comprises the silver-tin intermetallic compound (Ag₃Sn). Since the melting point of the silver-tin intermetallic compound (Ag₃Sn) is about 480° C., the thermoelectric module of Example 2 can be operated at temperatures higher than 232° C. and lower than 480° C. In addition, the bonding layer in the thermoelectric module of Example 2 is tested with a shear strength test, and the test result presents the bonding layer has a bonding strength about 6.8 MPa. In another case, the thermoelectric module is bonded under 2 MPa at a temperature about 250° C. for 10 minutes, which results in the fail of bonding. Increasing the pressure of thermocompression process from 2 MPa to 10 MPa leads to a bonding strength of 9.4 MPa.

### EXAMPLE 3

The thermoelectric module of Example 3 is formed by coating a tin layer having a thickness about 2 μm, a nickel layer having a thickness about 4 μm and a silver layer having a thickness about 10 μm on a p-type thermoelectric component (Pb_{0.5}Sn_{0.5}Te), and coating a silver layer having a thickness about 2 μm and a tin layer having a thickness about 4 μm on an copper electrode plate. After that, the thermoelectric component having the tin layer, the nickel layer and the silver layer and the copper electrode plate having the silver layer and the tin layer are stacked together, and then a thermocompression treatment is performed in a vacuum condition or an inert gas condition. The thermocompression treatment is performed under a pressure of 2 MPa at a temperature about 300° C. for 30 minutes, and the tin layer on the copper electrode plate is melted and quickly reacted with the silver layers on the thermoelectric component and the copper electrode plate to form a bonding layer comprising the silver-tin intermetallic compound (Ag₃Sn). The tin layer is quickly reacted and is completely consumed, and the silver layers are partially remained.

The bonding layer comprises the silver-tin intermetallic compound (Ag₃Sn). Since the melting point of the silver-tin intermetallic compound (Ag₃Sn) is about 480° C., the thermoelectric module of Example 3 can be operated at temperatures higher than 232° C. and lower than 480° C. In addition, the bonding layer in the thermoelectric module of Example 3 is tested with a shear strength test, and the test result presents the bonding layer has a bonding strength about 13.0 MPa. In another case, the thermoelectric module is bonded under 2 MPa at a temperature about 250° C. for 5 minutes, which results in a bonding strength of 4.2 MPa. Increasing the pressure of thermocompression process from 2 MPa to 9 MPa leads to a bonding strength of 15.8 MPa.

In the disclosure, the bonding layer comprises a silver-tin intermetallic compound, a nickel-tin intermetallic compound, or a copper-tin intermetallic compound. The bonding layer is formed at the temperature ranged from 235° C. to 350° C. and the thermoelectric module having the bonding layer can be safely operated between 350° C. and 400° C. Accordingly, the solid liquid inter-diffusion bonding structure of the thermoelectric module can be formed at a lower temperature and can be operated at a higher temperature.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A method of fabricating a solid-liquid interdiffusion bonding structure of a thermoelectric module, comprising:
forming a silver, nickel, or copper layer on at least one of a thermoelectric component and an electrode plate, and then forming a tin layer;
stacking the thermoelectric component and the electrode plate together and performing a thermocompression treatment, wherein the tin layer reacts with the silver, nickel, or copper layer to form a silver-tin intermetallic compound, a nickel-tin intermetallic compound, or a copper-tin intermetallic compound; and
performing a cooling step such that the thermoelectric component and the electrode plate are bonded together.

2. The method as claimed in claim 1, wherein the silver layer is formed on the at least one of the thermoelectric component and the electrode plate, and the formed silver-tin intermetallic compound comprises Ag₃Sn.

3. The method as claimed in claim 1, wherein the nickel layer is formed on the at least one of the thermoelectric component and the electrode plate, and the formed nickel-tin intermetallic compound comprises Ni₃Sn₄, Ni₃Sn₂, Ni₃Sn, or a combination thereof.

4. The method as claimed in claim 1, wherein the copper layer is formed on the at least one of the thermoelectric component and the electrode plate, and the formed copper-tin intermetallic compound comprises Cu₆Sn₅, Cu₃Sn, or a combination thereof.

5. The method as claimed in claim 1, wherein the tin layer completely reacts with the silver, nickel, or copper layer to form the silver-tin intermetallic compound, the nickel-tin intermetallic compound, or the copper-tin intermetallic compound, and the silver, nickel, or copper layer is partially remained.

6. The method as claimed in claim 1, wherein a thickness of the tin layer ranges from 1 μm to 10 μm.

7. The method as claimed in claim 1, wherein the thermocompression treatment is performed under a pressure of 1 MPa to 10 MPa at a temperature ranged from 235° C. to 350° C. for 3-60 minutes.

8. The method as claimed in claim 1, wherein the thermoelectric component comprises a p type thermoelectric material or an n type thermoelectric material which comprising an alloy series of Bi₂Te₃, GeTe, PbTe, CoSb₃, or Zn₄Sb₃.

9. The method as claimed in claim 1, wherein the silver, nickel, or copper layer and the tin layer are respectively formed with an electroplating process, an electroless plating process, a vacuum evaporation process, a sputtering process, or a chemical vapor deposition process.

10. A solid-liquid interdiffusion bonding structure of a thermoelectric module, comprising:
at least one thermoelectric component; and
at least one electrode plate, wherein a bonding layer is disposed between the thermoelectric component and the electrode plate so as to so bond the thermoelectric component and the electrode plate together, and the bonding layer comprises a silver-tin intermetallic compound, a nickel-tin intermetallic compound, or a copper-tin intermetallic compound.

11. The solid-liquid interdiffusion bonding structure as claimed in claim 10, wherein the silver-tin intermetallic compound comprises Ag₃Sn, the nickel-tin intermetallic compound comprises Ni₃Sn₄, Ni₃Sn₂, Ni₃Sn, or a combination thereof, and the copper-tin intermetallic compound comprises Cu₆Sn₅, Cu₃Sn, or a combination thereof.

12. The solid-liquid interdiffusion bonding structure as claimed in claim 10, wherein the bonding layer further comprises a residual layer of silver, nickel, or copper.

13. The solid-liquid interdiffusion bonding structure as claimed in claim 10, wherein the thermoelectric component comprises a p-type thermoelectric material or an n-type thermoelectric material which comprising an alloy series of Bi₂Te₃, GeTe, PbTe, CoSb₃, or Zn₄Sb₃.
